(19) United States
(12) Patent Application Publication
(10) Pub. No.: US 2020/0185555 A1
(43) Pub. Date: Jun. 11, 2020

(54) Array of Photovoltaic Cells

(71) Applicant: ROBERT E. SANDSTROM, Longview, WA (US)

(72) Inventor: ROBERT E. SANDSTROM, Longview, WA (US)

(21) Appl. No.: 16/210,401

(22) Filed: Dec. 5, 2018

(51) Int. Cl. H01L 31/047; H01L 31/02

(52) U.S. Cl. CPC H01L 31/047; H01L 31/02008

(57) ABSTRACT

A method of generating electricity from light that utilizes an array of photovoltaic cells, each including a junction between an electron-donating layer, and an electron-accepting layer, and wherein each cell produces a maximum current during exposure to light when it is exposed to a magnetic field having an optimal strength, and wherein the optimal magnetic field strength varies by more than 5% between the photovoltaic cells. For each the cell, a magnetic field is created in an optimal range of magnetic field strength, that is substantially unvarying over the electron donating layer, as the array is being exposed to light.

### BACKGROUND

Many different types of photo-voltaic cells have been developed, including crystalline silicon, thin film and multi-junction cells. Although these differing types of cells work along broadly similar principles, with photoactive compounds absorbing energy from photons leading to the production of electric power, the specifics vary broadly. In terms of commercialization, as of 2014, crystalline silicone cells were dominant.

Another type of photovoltaic cell, in development as of 2014, was the bulk heterojunction polymer photovoltaic cell. This type of cell included a polymer thin film having an interpenetrating network of a conjugated polymer donor such as poly(3-hexylthiophene-2,5-diyl) (P3HT) and a soluble fullerene acceptor which is typically [6,6]-phenyl-C61-butyric acid methyl ester (PCBM) as the photoactive layer. It has been observed, for this type of cell that the triplet state exitons were far more numerous and longer lasting than singlet state exitons. Accordingly, it was found that creating a weak magnetic field in the thin film had the effect of lowering the short-circuit current by increasing the population of triplet state exitons. W. F. Zhang, Y. Xu, H. T. Wang, C. H. Xu, S. F. Yang, Sol. Energy Mater. Sol. Cells 95(2011) 2880.

The experimenters who authored the above noted paper, however, took this result to be intimately tied to the exact nature of bulk heterojunction polymer cells, and they do not ever suggest that the result might be broadly generalizable.

Later, another group of researchers experimented with differing magnetic field strengths applied to dye-sensitized TᵢO₂ nanoparticle-based photovoltaic cells. Although power conversion efficiency was improved, it does not appear that the mechanism was the same as for the earlier experiment. The improvement in the J_{sc} and g observed in the low magnetic field was attributed to slow electron recombination predominantly caused by the variations of the local electronic surface properties of TᵢO₂. Magnetic-field enhanced photovoltaic performance of dye-sensitized TᵢO₂ nanoparticle-based solar cells Fengshi Cai, Shixin Zhang, Shuai Zhou, Zhihao Yuan.

Notably, both of these groups experimented and published results regarding photovoltaic cells that were largely made of an organic colloidal suspension or gel. Researchers far more readily view material of this sort from the point of view of chemistry, as this type of material can be probed and sampled fairly easily, thereby permitting an investigator to gather information regarding the internal dynamics of the material.

Moreover, despite the research noted above, it does not appear that this technology has been commercially utilized to enhance solar powered electricity generation.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

In a first separate aspect the present invention may take the form of a method of generating electricity from light that utilizes an array of photovoltaic cells, each including a junction between an electron-donating layer, and an electron-accepting layer, and wherein each cell produces a maximum current during exposure to light when it is exposed to a magnetic field having an optimal strength, and wherein the optimal magnetic field strength varies by more than 5% between the photovoltaic cells. For each the cell, a magnetic field is created in an optimal range of magnetic field strength, that is substantially unvarying over the electron donating layer, as the array is being exposed to light.

In a second separate aspect, the present invention may take the form of an electricity generating assembly, having an array of photovoltaic cells, each including a junction between an electron-donating layer, and an electron-accepting layer, and wherein each cell produces a maximum current during exposure to light when it is exposed to a magnetic field having an optimal strength, and wherein the optimal magnetic field strength varies by more than 5% between the photovoltaic cells. For each cell, a magnet creating a magnetic field in an optimal range of magnetic field strength, that is substantially unvarying over the electron donating layer, as the array is being exposed to light.

In addition to the exemplary aspects and embodiments described above, further aspects and embodiments will become apparent by reference to the drawings and by study of the following detailed descriptions.

### BRIEF DESCRIPTION OF THE DRAWINGS

Exemplary embodiments are illustrated in referenced drawings. It is intended that the embodiments and figures disclosed herein are to be considered illustrative rather than restrictive.

FIG. 1 is a front view of a photovoltaic assembly, according to the present invention.

FIG. 2A is an illustration of the operation of a photovoltaic cell, in the absence of magnetic field effects.

FIG. 2B is an illustration of the operation of a photovoltaic cell, in the presence of magnetic field effects.

FIG. 3A is an illustration of the operation of a photovoltaic cell assembly, in the presence of magnetic field effects created by a magnetic film, that is part of the assembly.

FIG. 3B is an illustration of the operation of a photovoltaic cell assembly, in the presence of magnetic field effects created by magnetic particles mixed into a layer of the cell.

FIG. 4 is an illustration of an array of photovoltaic cells, according to a further aspect of the present invention.

### DETAILED DESCRIPTION OF THE PREFERRED EMBODIMENTS

Many photovoltaic cells function by having an electron-donating layer made of a material. When struck by a photon of correct energy an electron is freed, thereby creating a potential flow of electricity. But the electron and the moiety from which it has been freed are likely to recombine, ending this process. When the electron-donating layer is a solid, the terminology used to describe the phenomenon of the freed electron and the moiety now missing an electron, having its origin in solid state research, is “active electron” and “hole” often referred to as an “exciton.” Terminology varies but when an entity is produced that has an unpaired orbital electron and a free electron, the system is the equivalent of a free radical and a freed electron and is termed a “free radical equivalent” herein.

It is possible for a liquid, colloidal suspension or a gel to demonstrate that the “hole” actually displays the same characteristics, in terms of magnetic precession, as a free radical. In fact, what has been termed a “hole” in solid state research is a “free radical” but has simply not heretofore been recognized as such. Accordingly, a magnetic field that acts to forestall the recombination of free radicals with active electrons will increase the quantity of free electrons available for transport and therefore the efficiency of the photovoltaic cell. In particular a magnetic field that maintains free radicals in the triplet state, which greatly reduces the chance of recombination, will increase the number of active electrons and increase the efficiency of the photovoltaic cell.

Some of the research referenced in the Background section involved the mixing of magnetic particles into a photosensitive layer. This naturally causes a magnetic field that varies with range to the nearest magnetic particle. A magnetic field at the optimal strength that does not vary significantly over the expanse of the electron-donating layer of photosensitive material will yield a greater increase in photovoltaic cell efficiency.

The vast bulk of photo-voltaic cells in operation as of 2014 include an electron-donating layer comprising a silicon based material, such as monocrystalline silicon, polycrystalline silicon (including ribbon silicon) or amorphous silicon. Other materials placed in commercial use, in thin film structures in which the thickness of the electron-donating layer is less than 40 μm and could be as thin as 2 nm, include cadmium telluride (CdTe), copper indium gallium diselenide (CIGS). Amorphous silicon and crystalline silicon is also used in thin film applications.

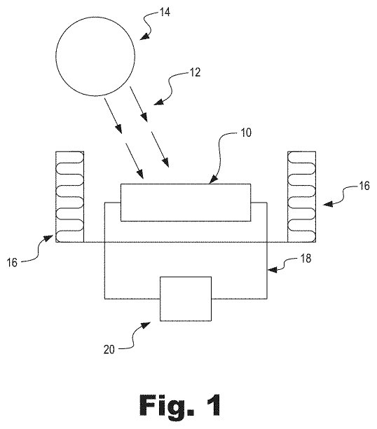

Referring to FIG. 1, a photovoltaic cell 10, is exposed to photons (light) 12, from the sun 14 and simultaneously exposed to a uniform magnetic field produced by a Helmholtz coil or array of such coils. 16. Electrons produced the photovoltaic cell are connected by an electric circuit 18, to an electric load 20, which may be, more specifically, an electric storage device. In the alternative a balanced arrangement of permanent magnets or a solid layer of such magnets may replace the Helmholtz coils 16, to achieve a similar effect.

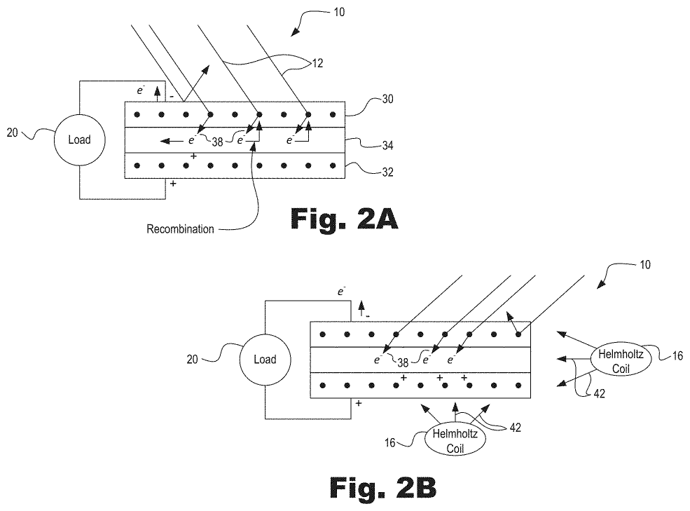

FIGS. 2A and 2B illustrate the effect of the magnetic field on the activity of freed electrons. In FIG. 2A, a photovoltaic cell 10 includes an electron-donating layer 30 is joined to an electron-accepting layer 32 by a junction (shown in greatly expanded form) where the process is unaffected by a magnetic field, photons 12 striking the n-type semiconductor free three electrons 38 (as an illustration) into the junction 34. One of these flows to the load 20, thereby forming a part of the current produced by the cell 10. But the other two recombine into the electron-donating layer (shortly after forming), typically into the same moiety from which the particular electron 38 originated. As shown in FIG. 2B, in the same photovoltaic cell the magnetic field 42 (generated from Helmholtz coils 16 shown in completely conceptual form) prevents some of the electrons 38 from recombining back into the moiety from which they came, so they join the flow to the load 20. Skilled persons will understand that this is merely an illustration, and that in reality even with the magnetic field, many electrons recombine into the moiety from which they were ejected. The magnetic field, however, by causing more free radicals to remain in the triplet state, prevents many recombinations, and thereby contributes to the flow of electricity.

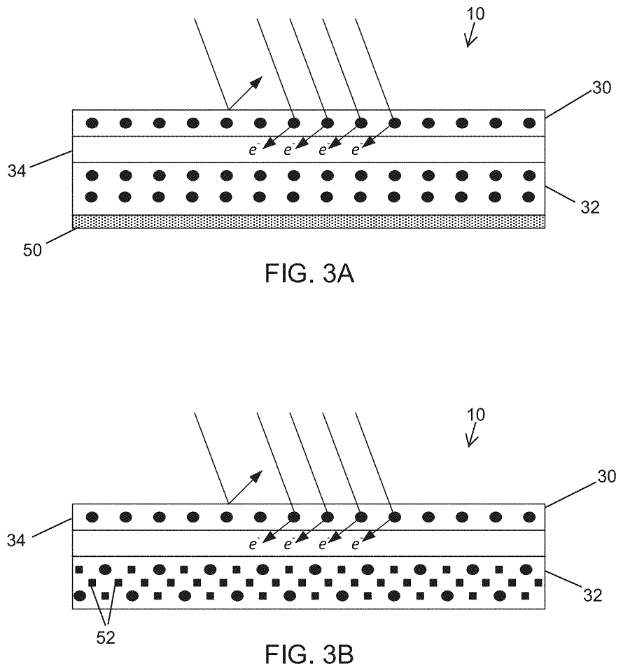

As shown in FIG. 3A, in an additional preferred embodiment a magnetic paint or film 50 is positioned adjacent to electron-accepting layer 32 and configured to produce a magnetic field of a beneficial magnitude for preventing the recombination of electrons donated by electron-donating layer 30 back into layer 30 after having entered the junction 34. In an alternative preferred embodiment, a magnetic film is placed into electron-donating layer 30 with the same object of placing a beneficial magnetic field at junction 34.

In FIG. 3B magnetic particles 52 are mixed into the electron-accepting layer 32, to create a uniform magnetic field at the junction 34. In one preferred embodiment particles 52 have an average major axis of less than a micrometer. In an alternative preferred embodiment, particles 52 are mixed into the electron-donating layer 30, to place a uniform magnetic field on junction 34. In another alternative, particles 52 are mixed into both electron-accepting layer 32 and electron-donating layer 30.

In one set of embodiments electron-donating layer 30 and electron-accepting layer 34 are both made of similar material, such as crystalline silicon, but where electron donating layer 30 is n-type and electron-accepting layer 34 is p-type. If comprised of crystalline silicon, layers 30 and 34 may be either monocrystalline silicon or polycrystalline silicon. Alternatively layers 30 and 34 are comprised of amorphous silicon or a thin film material such as CdTe or CIGS. In an alternative set of embodiments, the electron-donating layer 30 is comprised of conjugated polymers and the electron-accepting layer 34 is comprised of inorganic nanocrystals. In an alternative preferred embodiment electron-donating layer 30 or electron-accepting layer 32 or both are made of a perovskite.

For each one of the above recited materials, there is a corresponding magnetic field strength that will typically have a value of between 10 and 100 gauss (1 and 10 millitesla) that optimally extends the triplet state lifetimes in free radicals formed in the material. Moreover, manufacturing photovoltaic cells is not 100% repeatable. That is to say, despite best efforts, it appears that it is not possible to produce a sequence of photovoltaic panels wherein each one has the exact same optimum electromagnetic field, because of unavoidable small differences in the physical structure of the photovoltaic cells, on a molecular level. The responsiveness of a photovoltaic cell to an electromagnetic field can be quite specific, with differences noted in current output for changes in magnetic field strength on the order of one-tenth of a Gauss. Accordingly, to achieve the best output from a photovoltaic array, it is necessary to determine the best magnetic field strength for each cell, separately. Pre-knowledge of the cell characteristics can be used to help set the starting part for the calibration routine, but from this starting point steps of magnetic field strength magnitude are taken, with resultant current measured, as light hitting the cell is held constant.

To determine the optimal magnetic field strength an experiment may be configured by taking a photovoltaic cell 10 and placing it between two Helmholtz coils 16, as shown in FIG. 1. A light 12 having known characteristics is then shined upon the photovoltaic cell and various magnetic field strengths are applied, with the resultant electric current produced by the photovoltaic cell measured. In one preferred method a time period, wherein, no magnetic field is applied is interspersed between the times when a magnetic field is applied, to eliminate the effect of the previous test for magnetic field effect. When a pair of magnetic field strength values are found that are close together and yield a higher current than other field strengths tested, the step size is reduced, and readings are taken for fields between these two field strengths, to determine if some intermediate field strength yields a current that is higher still. In one embodiment, step sizes of one millitesla are used in the beginning calibration, and then for finer calibration, step sizes of 0.1 millitesla (1 Gauss), and for an even finer calibration, step sizes of one-tenth of a Gauss are used.

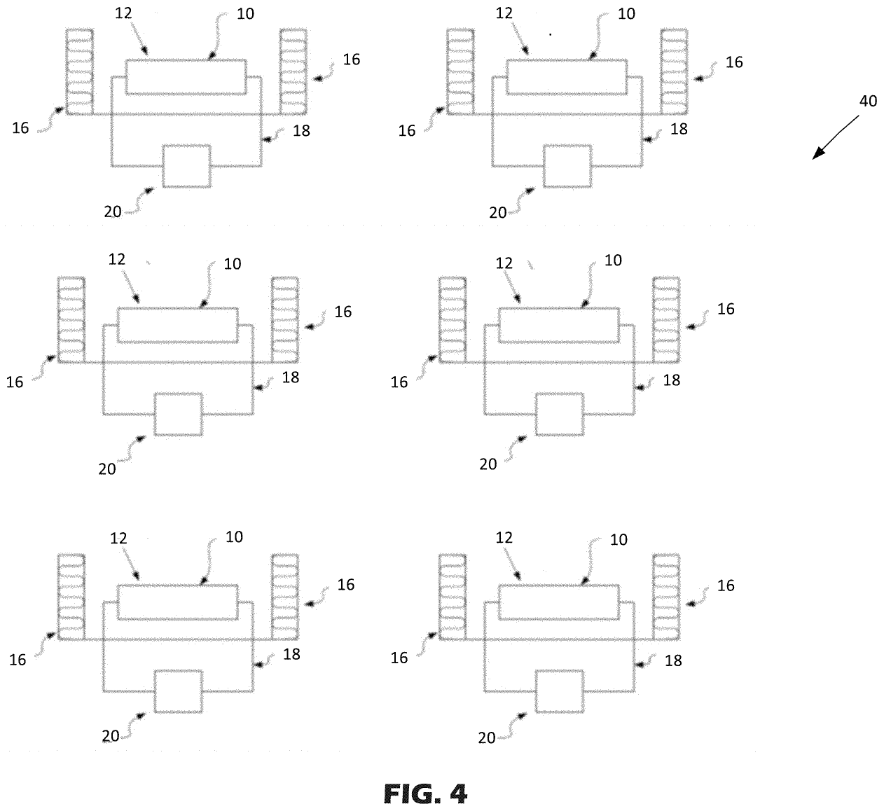

Often, electric power is generated by an array of photovoltaic cells, all of apparently identical construction. It is quite difficult, however, to repeatably create photovoltaic cells for which the optimal magnetic field strength is exactly the same. Small differences in doping levels of the electron donating and electron receiving layers can have a significant impact on the optimal magnetic field strength. Accordingly, referring to FIG. 4, a new form of an array 40 of photo voltaic cells 10 is disclosed herein, in which each photovoltaic cell 10 is calibrated for its optimum magnetic field, by a calibration method such as that described above. Each cell 10 of the array 40 is then exposed to its optimum strength magnetic field, produced by a Helmholtz coil 16 specifically tuned to produce a magnetic field that is at its optimum strength at the electron donating layer of the photovoltaic cell 10, to which the Helmholtz coil 16 is paired, as the photovoltaic cell is exposed to light (preferably sunlight) 12 to generate electricity, consumed by load 20.

While a number of exemplary aspects and embodiments have been discussed above, those possessed of skill in the art will recognize certain modifications, permutations, additions and sub-combinations thereof. It is therefore intended that the following appended claims and claims hereafter introduced are interpreted to include all such modifications, permutations, additions and sub-combinations as are within their true spirit and scope.

1. A method of generating electricity from light, comprising:
(a) providing an array of photovoltaic cells, each including a junction between an electron-donating layer, and an electron-accepting layer, and wherein each cell produces a maximum current during exposure to light when it is exposed to a magnetic field having an optimal strength, and wherein said optimal magnetic field strength varies by more than 5% between said photovoltaic cells; and
(b) for each said cell, creating a magnetic field in an optimal range of magnetic field strength, that is substantially unvarying over said electron donating layer, as said array is being exposed to light.

2. The method of claim 1, including, for each said photo-voltaic cell, performing an initial calibration process, to determine an optimal magnetic field strength for said cell.

3. The method of claim 2, wherein said initial calibration process determines the optimal magnetic field strength to within a 10 Gauss range.

4. The method of claim 2, wherein said initial calibration process determines the optimal magnetic field strength to within a 5 Gauss range.

5. The method of claim 2, wherein said initial calibration process determines the optimal magnetic field strength to within a 2 Gauss range.

6. The method of claim 2, wherein said initial calibration process determines the optimal magnetic field strength to within a 1 Gauss range.

7. The method of claim 2, wherein said initial calibration process determines the optimal magnetic field strength to within a 0.5 Gauss range.

8. The method of claim 2, wherein said initial calibration process determines the optimal magnetic field strength to within a 0.2 Gauss range.

9. The method of claim 2, wherein said initial calibration process determines the optimal magnetic field strength to with a 0.1 Gauss range.

10. The method of claim 1, wherein said photo-voltaic cells are provided with optimal magnetic field strength range already determined.

11. The method of claim 1, wherein said photo-voltaic cells are as similar to one another as possible using available manufacturing processes.

12. The method of claim 1, wherein each said photo-voltaic cell is made of the same materials as all the other photo-voltaic cells in said array.

13. The method of claim 1, wherein for each said photo-voltaic cell said electron donating and said electron accepting layer is made of inorganic crystalline material.

14. The method of claim 1, wherein each said photo-voltaic cell is comprised of silicon.

15. An electricity generating assembly, comprising:
(a) an array of photovoltaic cells, each including a junction between an electron-donating layer, and an electron-accepting layer, and wherein each cell produces a maximum current during exposure to light when it is exposed to a magnetic field having an optimal strength, and wherein said optimal magnetic field strength varies by more than 5% between said photovoltaic cells; and
(b) for each said cell, a magnet creating a magnetic field in an optimal range of magnetic field strength, that is substantially unvarying over said electron donating layer, as said array is being exposed to light.

16. The assembly of claim 15, wherein said electron-donating layer and said electron-accepting layer are made of crystalline material.

17. The assembly of claim 16, wherein said crystalline material is crystalline silicon.

18. The assembly of claim 17, wherein said crystalline silicone is polycrystalline silicon.

19. The assembly of claim 18, wherein said polycrystalline silicon is ribbon silicon.

20. The assembly of claim 17, wherein said crystalline silicon is monocrystalline silicon.
